(19) United States
(12) Patent Application Publication
(10) Pub. No.: US 2016/0183382 A1
(43) Pub. Date: Jun. 23, 2016

(54) CAPACITIVE IMAGE SENSOR WITH SELECTABLE FUNCTION ELECTRODES

(71) Applicant: Synaptics Incorporated, San Jose, CA (US)

(72) Inventors: Derek SOLVEN, San Jose, CA (US); Adam SCHWARTZ, Redwood City, CA (US)

(21) Appl. No.: 14/579,683

(22) Filed: Dec. 22, 2014

(51) Int. Cl. H05K 3/32; G06F 3/041; G06F 1/16; H05K 3/36; G06F 3/044

(52) U.S. Cl. CPC H05K 3/32; H05K 3/36; G06F 3/044; G06F 1/16; G06F 3/0416; G06F 2203/04103; G06F 2203/04108

(57) ABSTRACT

In an example, a capacitive image sensor comprises a first sensor electrode, a second sensor electrode, and a third sensor electrode. The first sensor electrode is disposed on a first surface of a substrate configured to transmit a transmitter signal. The second sensor electrode is disposed on the first surface of the substrate configured to receive a resulting signal. The third sensor electrode is disposed on the first surface of the substrate such that the second sensor electrode is at least partially between the first sensor electrode and the third sensor electrode.

### BACKGROUND

1. Field of the Disclosure

Embodiments generally relate to input sensing and, in particular, to a capacitive image sensor with selective function electrodes.

2. Description of the Related Art

Input devices including proximity sensor devices (also commonly called touchpads or touch sensor devices) are widely used in a variety of electronic systems. A proximity sensor device typically includes a sensing region, often demarked by a surface, in which the proximity sensor device determines the presence, location, and/or motion of one or more input objects. Input objects can be at or near the surface of the proximity sensor device (“touch sensing”) or hovering over the surface of the proximity sensor device (“proximity sensing” or “hover sensing”). Proximity sensor devices may be used to provide interfaces for the electronic system. For example, proximity sensor devices are often used as input devices for larger computing systems (such as touchpads integrated in, or peripheral to, notebook or desktop computers). Proximity sensor devices are also often used in smaller computing systems (such as touch screens integrated in cellular phones or tablet computers).

Proximity sensor devices are typically used in combination with other supporting components, such as display or input devices found in the electronic or computing system. In some configurations, the proximity sensor devices are coupled to these supporting components to provide a desired combined function or to provide a desirable complete device package. Many commercially available proximity sensor devices utilize one or more electrical techniques to determine the presence, location and/or motion of an input object, such as a capacitive or a resistive sensing technique. Typically, the proximity sensor devices utilize an array of sensor electrodes to detect the presence, location and/or motion of an input object. Due to the often large number of sensor electrodes used to sense the presence and position of an input object with desirable accuracy, and also the need to connect each of these sensor electrodes to the various signal generation and data collection components in the electronic or computing system, the cost associated with forming these interconnections, the reliability of the system and the overall size of the of the proximity sensor device are often undesirably large and complex. It is a common goal in the consumer and industrial electronics industries to reduce the cost and/or size of the electrical components in the formed electronic device. One will note that the cost and size limitations placed on the proximity sensor device are often created by the number of traces that are required, the number of required connection points, the connection component's complexity (e.g., number of pins on a connector) and the complexity of the flexible components used to interconnect the sensor electrodes to the control system.

### SUMMARY

Embodiments relate to a capacitive image sensor with selective function electrodes. In an embodiment, a capacitive image sensor comprises a first sensor electrode, a second sensor electrode, and a third sensor electrode. The first sensor electrode is disposed on a first surface of a substrate configured to transmit a transmitter signal. The second sensor electrode is disposed on the first surface of the substrate configured to receive a resulting signal. The third sensor electrode is disposed on the first surface of the substrate such that the second sensor electrode is at least partially between the first sensor electrode and the third sensor electrode.

In an embodiment, a method of manufacturing display panels comprises receiving a first color filter (CF) glass substrate patterned using a first CF mask, the first CF glass substrate including a first plurality of electrodes comprising transmitter electrodes, receiver electrodes, and undifferentiated electrodes; receiving a second CF glass substrate patterned using the first CF mask, the second CF glass substrate including a second plurality of electrodes comprising transmitter electrodes, receiver electrodes, and undifferentiated electrodes; coupling the first CF glass substrate to a first flexible printed circuit (FPC) for a first display panel such that the undifferentiated electrodes of the first plurality of electrodes are each conductively coupled to one or more of the transmitter electrodes of the first plurality of electrodes; and coupling the second CF glass substrate to a second FPC for a second display panel such that the undifferentiated electrodes of the second plurality of electrodes are coupled to a common bus.

In an embodiment, a processing system for a capacitive input device comprises a sensor module including sensor circuitry coupled to a plurality of sensor electrodes on a first surface of a substrate, the sensor module configured to: drive first sensor electrodes of the plurality of sensor electrodes with transmitter signals; receive resulting signals from second sensor electrodes of the plurality of sensor electrodes; and drive third sensor electrodes of the plurality of sensor electrodes with the transmitter signals or a substantially constant voltage, the third sensor electrodes disposed on the first surface of the substrate such that the second sensor electrodes are between the first sensor electrodes and the third sensor electrodes.

### BRIEF DESCRIPTION OF THE DRAWINGS

So that the manner in which the above recited features of embodiments can be understood in detail, a more particular description of embodiments, briefly summarized above, may be had by reference to embodiments, some of which are illustrated in the appended drawings. It is to be noted, however, that the appended drawings illustrate only typical embodiments and are therefore not to be considered limiting of scope, for other equally effective embodiments may be admitted.

FIG. 1 is a block diagram of a system that includes an input device according to an example implementation.

FIG. 2 is an exploded side view of a display device having an integrated input device according to an example implementation.

FIG. 3A is a schematic top view of a sensor electrode pattern that may be used to sense input object(s) in the sensing region of the input device of FIG. 1.

FIG. 3B is a schematic top view of an example of an electrode array.

FIG. 3C is a schematic top view of another example of an electrode array.

FIG. 4 is a schematic top view of a configuration of the input device of FIG. 1 that that may be used to sense input object(s) in the sensing region.

FIG. 5 is a schematic top view of another configuration of the input device of FIG. 1 that that may be used to sense input object(s) in the sensing region.

FIG. 6 is a flow diagram depicting an example method of manufacturing display panels.

FIG. 7 is a schematic top view of another configuration of the input device of FIG. 1 that that may be used to sense input object(s) in the sensing region.

To facilitate understanding, identical reference numerals have been used, where possible, to designate identical elements that are common to the figures. It is contemplated that elements of one embodiment may be beneficially incorporated in other embodiments.

### DETAILED DESCRIPTION

The following detailed description is merely exemplary in nature and is not intended to limit the embodiments or the application and uses of such embodiments. Furthermore, there is no intention to be bound by any expressed or implied theory presented in the preceding technical field, background, brief summary or the following detailed description.

Various embodiments relate to a capacitive image sensor with selective function electrodes. Input devices integrated into a display device can include sensor electrodes formed on a single layer of the display, such as an active liquid crystal display (LCD), for capacitive sensing. During manufacture of the display, the sensor electrodes can be patterned on a layer in the LCD stack, such as on a color filter glass layer. The LCD stack can vary across display devices in terms of materials of the layers and thickness of the layers. Different LCD stacks can present different problems for capacitive sensing: Thin, high dielectric stacks can suffer from low ground mass (LGM) problems, which thick, lower dielectric stacks can suffer from low signal strength at the sensor. Embodiments described herein provide a common sensor electrode pattern that can be used on a layer of the LCD stack (e.g., color filter glass) across different stack configurations. The common sensor electrode pattern can be modified external to the LCD stack in order to support different capacitive sensing configurations based on the configuration of the stack. In some examples described herein, the configuration of the sensor electrode pattern is modified using a connection medium between the sensor electrodes and a processing system, such as a flexible printed circuit (FPC). In this manner, LCD manufacturers (LCMs) can use a single mask to create the layer on which the sensor electrodes are formed. Design performance of the capacitive sensing device can be modified by changing only the connection medium, rather than changing the mask used to form a layer in the display stack. These and further aspects are described further below.

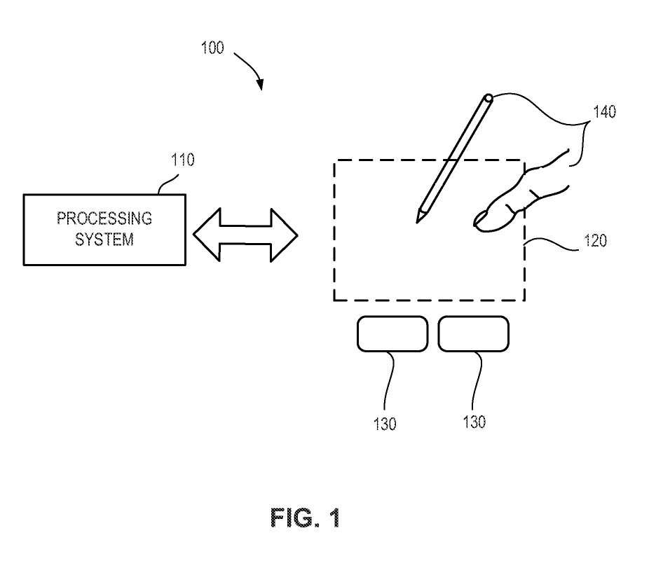

Turning now to the figures, FIG. 1 is a block diagram of an exemplary input device 100, in accordance with embodiments of the invention. The input device 100 may be configured to provide input to an electronic system (not shown). As used in this document, the term “electronic system” (or “electronic device”) broadly refers to any system capable of electronically processing information. Some non-limiting examples of electronic systems include personal computers of all sizes and shapes, such as desktop computers, laptop computers, netbook computers, tablets, web browsers, e-book readers, and personal digital assistants (PDAs). Additional example electronic systems include composite input devices, such as physical keyboards that include input device 100 and separate joysticks or key switches. Further example electronic systems include peripherals such as data input devices (including remote controls and mice), and data output devices (including display screens and printers). Other examples include remote terminals, kiosks, and video game machines (e.g., video game consoles, portable gaming devices, and the like). Other examples include communication devices (including cellular phones, such as smart phones), and media devices (including recorders, editors, and players such as televisions, set-top boxes, music players, digital photo frames, and digital cameras). Additionally, the electronic system could be a host or a slave to the input device.

The input device 100 can be implemented as a physical part of the electronic system, or can be physically separate from the electronic system. As appropriate, the input device 100 may communicate with parts of the electronic system using any one or more of the following: buses, networks, and other wired or wireless interconnections. Examples include I²C, SPI, PS/2, Universal Serial Bus (USB), Bluetooth, RF, and IRDA.

In FIG. 1, the input device 100 is shown as a proximity sensor device (also often referred to as a “touchpad” or a “touch sensor device”) configured to sense input provided by one or more input objects 140 in a sensing region 120. Example input objects include fingers and styli, as shown in FIG. 1.

Sensing region 120 encompasses any space above, around, in and/or near the input device 100 in which the input device 100 is able to detect user input (e.g., user input provided by one or more input objects 140). The sizes, shapes, and locations of particular sensing regions may vary widely from embodiment to embodiment. In some embodiments, the sensing region 120 extends from a surface of the input device 100 in one or more directions into space until signal-to-noise ratios prevent sufficiently accurate object detection. The distance to which this sensing region 120 extends in a particular direction, in various embodiments, may be on the order of less than a millimeter, millimeters, centimeters, or more, and may vary significantly with the type of sensing technology used and the accuracy desired. Thus, some embodiments sense input that comprises no contact with any surfaces of the input device 100, contact with an input surface (e.g. a touch surface) of the input device 100, contact with an input surface of the input device 100 coupled with some amount of applied force or pressure, and/or a combination thereof. In various embodiments, input surfaces may be provided by surfaces of casings within which the sensor electrodes reside, by face sheets applied over the sensor electrodes or any casings, etc. In some embodiments, the sensing region 120 has a rectangular shape when projected onto an input surface of the input device 100.

The input device 100 may utilize any combination of sensor components and sensing technologies to detect user input in the sensing region 120. The input device 100 comprises one or more sensing elements for detecting user input. As several non-limiting examples, the input device 100 may use capacitive, elastive, resistive, inductive, magnetic, acoustic, ultrasonic, and/or optical techniques.

Some implementations are configured to provide images that span one, two, three, or higher dimensional spaces. Some implementations are configured to provide projections of input along particular axes or planes.

In some capacitive implementations of the input device 100, voltage or current is applied to create an electric field. Nearby input objects cause changes in the electric field, and produce detectable changes in capacitive coupling that may be detected as changes in voltage, current, or the like.

Some capacitive implementations utilize arrays or other regular or irregular patterns of capacitive sensing elements to create electric fields. In some capacitive implementations, separate sensing elements may be ohmically shorted together to form larger sensor electrodes. Some capacitive implementations utilize resistive sheets, which may be uniformly resistive.

Some capacitive implementations utilize “self capacitance” (or “absolute capacitance”) sensing methods based on changes in the capacitive coupling between sensor electrodes and an input object. In various embodiments, an input object near the sensor electrodes alters the electric field near the sensor electrodes, thus changing the measured capacitive coupling. In one implementation, an absolute capacitance sensing method operates by modulating sensor electrodes with respect to a reference voltage (e.g. system ground), and by detecting the capacitive coupling between the sensor electrodes and input objects.

Some capacitive implementations utilize “mutual capacitance” (or “transcapacitance”) sensing methods based on changes in the capacitive coupling between sensor electrodes. In various embodiments, an input object near the sensor electrodes alters the electric field between the sensor electrodes, thus changing the measured capacitive coupling. In one implementation, a transcapacitive sensing method operates by detecting the capacitive coupling between one or more transmitter sensor electrodes (also “transmitter electrodes” or “transmitters”) and one or more receiver sensor electrodes (also “receiver electrodes” or “receivers”). Transmitter sensor electrodes may be modulated relative to a reference voltage (e.g., system ground) to transmit transmitter signals. Receiver sensor electrodes may be held substantially constant relative to the reference voltage to facilitate receipt of resulting signals. A resulting signal may comprise effect(s) corresponding to one or more transmitter signals, and/or to one or more sources of environmental interference (e.g. other electromagnetic signals). Sensor electrodes may be dedicated transmitters or receivers, or may be configured to both transmit and receive.

In FIG. 1, a processing system 110 is shown as part of the input device 100. The processing system 110 is configured to operate the hardware of the input device 100 to detect input in the sensing region 120. The processing system 110 comprises parts of or all of one or more integrated circuits (ICs) and/or other circuitry components. For example, a processing system for a mutual capacitance sensor device may comprise transmitter circuitry configured to transmit signals with transmitter sensor electrodes, and/or receiver circuitry configured to receive signals with receiver sensor electrodes. In some embodiments, the processing system 110 also comprises electronically-readable instructions, such as firmware code, software code, and/or the like. In some embodiments, components composing the processing system 110 are located together, such as near sensing element(s) of the input device 100. In other embodiments, components of processing system 110 are physically separate with one or more components close to sensing element(s) of input device 100, and one or more components elsewhere. For example, the input device 100 may be a peripheral coupled to a desktop computer, and the processing system 110 may comprise software configured to run on a central processing unit of the desktop computer and one or more ICs (perhaps with associated firmware) separate from the central processing unit. As another example, the input device 100 may be physically integrated in a phone, and the processing system 110 may comprise circuits and firmware that are part of a main processor of the phone. In some embodiments, the processing system 110 is dedicated to implementing the input device 100. In other embodiments, the processing system 110 also performs other functions, such as operating display screens, driving haptic actuators, etc.

The processing system 110 may be implemented as a set of modules that handle different functions of the processing system 110. Each module may comprise circuitry that is a part of the processing system 110, firmware, software, or a combination thereof. In various embodiments, different combinations of modules may be used. Example modules include hardware operation modules for operating hardware such as sensor electrodes and display screens, data processing modules for processing data such as sensor signals and positional information, and reporting modules for reporting information. Further example modules include sensor operation modules configured to operate sensing element(s) to detect input, identification modules configured to identify gestures such as mode changing gestures, and mode changing modules for changing operation modes.

In some embodiments, the processing system 110 responds to user input (or lack of user input) in the sensing region 120 directly by causing one or more actions. Example actions include changing operation modes, as well as GUI actions such as cursor movement, selection, menu navigation, and other functions. In some embodiments, the processing system 110 provides information about the input (or lack of input) to some part of the electronic system (e.g. to a central processing system of the electronic system that is separate from the processing system 110, if such a separate central processing system exists). In some embodiments, some part of the electronic system processes information received from the processing system 110 to act on user input, such as to facilitate a full range of actions, including mode changing actions and GUI actions.

For example, in some embodiments, the processing system 110 operates the sensing element(s) of the input device 100 to produce electrical signals indicative of input (or lack of input) in the sensing region 120. The processing system 110 may perform any appropriate amount of processing on the electrical signals in producing the information provided to the electronic system. For example, the processing system 110 may digitize analog electrical signals obtained from the sensor electrodes. As another example, the processing system 110 may perform filtering or other signal conditioning. As yet another example, the processing system 110 may subtract or otherwise account for a baseline, such that the information reflects a difference between the electrical signals and the baseline. As yet further examples, the processing system 110 may determine positional information, recognize inputs as commands, recognize handwriting, and the like.

“Positional information” as used herein broadly encompasses absolute position, relative position, velocity, acceleration, and other types of spatial information. Exemplary “zero-dimensional” positional information includes near/far or contact/no contact information. Exemplary “one-dimensional” positional information includes positions along an axis. Exemplary “two-dimensional” positional information includes motions in a plane. Exemplary “three-dimensional” positional information includes instantaneous or average velocities in space. Further examples include other representations of spatial information. Historical data regarding one or more types of positional information may also be determined and/or stored, including, for example, historical data that tracks position, motion, or instantaneous velocity over time.

In some embodiments, the input device 100 is implemented with additional input components that are operated by the processing system 110 or by some other processing system. These additional input components may provide redundant functionality for input in the sensing region 120, or some other functionality. FIG. 1 shows buttons 130 near the sensing region 120 that can be used to facilitate selection of items using the input device 100. Other types of additional input components include sliders, balls, wheels, switches, and the like. Conversely, in some embodiments, the input device 100 may be implemented with no other input components.

In some embodiments, the input device 100 comprises a touch screen interface, and the sensing region 120 overlaps at least part of an active area of a display screen. For example, the input device 100 may comprise substantially transparent sensor electrodes overlaying the display screen and provide a touch screen interface for the associated electronic system. The display screen may be any type of dynamic display capable of displaying a visual interface to a user, and may include any type of light emitting diode (LED), organic LED (OLED), cathode ray tube (CRT), liquid crystal display (LCD), plasma, electroluminescence (EL), or other display technology. The input device 100 and the display screen may share physical elements. For example, some embodiments may utilize some of the same electrical components for displaying and sensing. As another example, the display screen may be operated in part or in total by the processing system 110.

It should be understood that while many embodiments of the invention are described in the context of a fully functioning apparatus, the mechanisms of the present invention are capable of being distributed as a program product (e.g., software) in a variety of forms. For example, the mechanisms of the present invention may be implemented and distributed as a software program on information bearing media that are readable by electronic processors (e.g., non-transitory computer-readable and/or recordable/writable information bearing media readable by the processing system 110). Additionally, the embodiments of the present invention apply equally regardless of the particular type of medium used to carry out the distribution. Examples of non-transitory, electronically readable media include various discs, memory sticks, memory cards, memory modules, and the like. Electronically readable media may be based on flash, optical, magnetic, holographic, or any other storage technology.

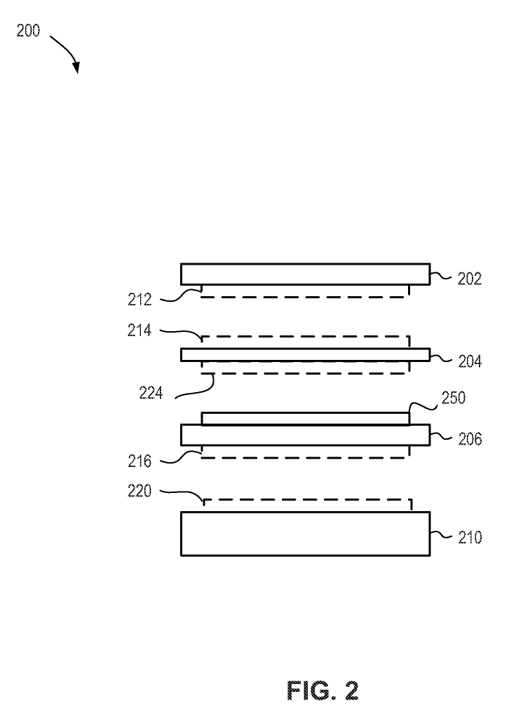

FIG. 2 is an exploded side view of a display device 200 having an integrated input device according to an example implementation. FIG. 2 shows alternative locations for a layer having sensor electrodes 250 of the input device 100. The display device 200 generally includes a plurality of transparent substrates over a substrate 210 (e.g., thin-film transistor (TFT) glass). In an example, the transparent substrates include a lens 202, an optional polarizer 204, and a color filter glass 206. In one example, the sensor electrodes 250 are disposed on a surface of the color filter glass 206 between the color filter glass 206 and the optional polarizer 204. Alternative locations for the sensor electrodes 250 are shown in phantom and include a location 220 on a surface of the substrate 210, a location 216 the other surface of the color filter glass 206 facing the substrate 210, locations 214 or 224 on a surface of the optional polarizer 204, or a location 212 on a surface of the lens 202 facing the optional polarizer 204. As described below, the sensor electrodes 250 may be divided into receiver electrodes, transmitter electrodes, and undifferentiated electrodes. The different types of sensor electrodes are ohmically isolated from one another on the substrate.

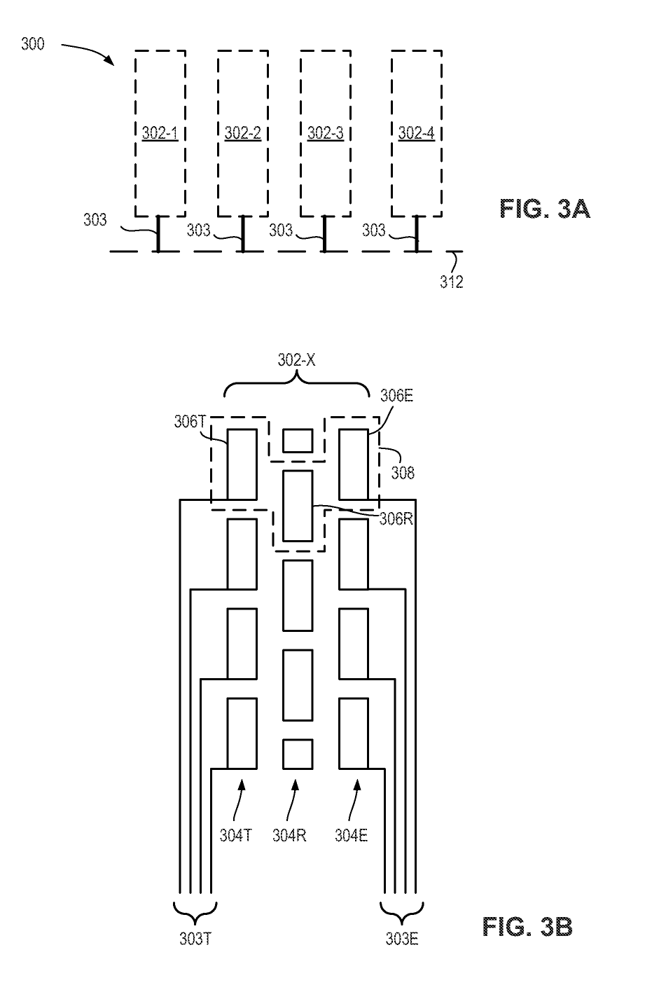

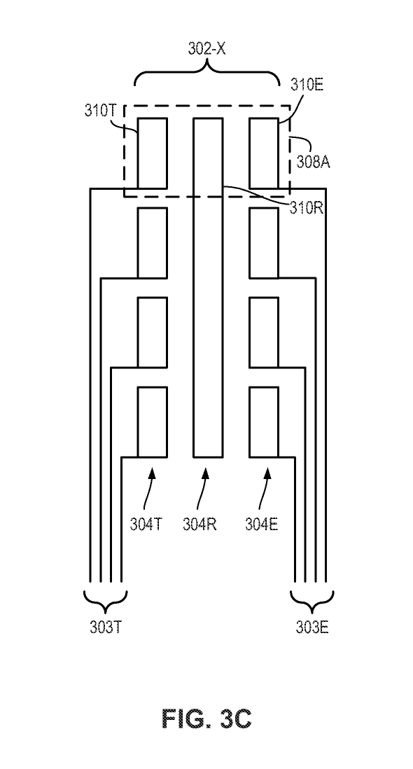

FIG. 3A is a schematic top view of a sensor electrode pattern 300 that may be used to sense input object(s) in the sensing region 120 of the input device 100. The sensor electrode pattern 300 can be disposed on a substrate that comprises a layer of a display device (e.g., the color filter glass 206). The sensor electrode pattern 300 includes a plurality of electrode arrays 302 (e.g., four electrode arrays 302-1, 302-2, 302-3, and 302-4 are shown). Each of the electrode arrays 302 is conductively coupled to a plurality of traces 303 that extend to an edge 312 of the substrate for coupling to a connection medium.

FIG. 3B is a schematic top view of an electrode array 302-X of the electrode arrays 302. The electrode array 302-X is representative of each of the electrode arrays 302. The electrode array 302-X includes three electrode columns 304T, 304R, and 304E (generally referred to as electrode columns 304). The sensor electrodes in an electrode column 304T are referred to as “transmitter electrodes”, the sensor electrodes in an electrode column 304R are referred to as “receiver electrodes”, and the sensor electrodes in an electrode column 304E are referred to as “undifferentiated electrodes”. Note that the terms “transmitter” and “receiver” as applied to the sensor electrodes in the sensor electrode pattern 300 are not meant to limit the sensor electrodes to any particular sensing scheme. While the terms “transmitter” and “receiver” are generally used with respect to transcapacitive sensing schemes, the sensor electrodes in the sensor electrode pattern 300 can also be used in absolute capacitive sensing schemes. Further, in some schemes, the electrodes designated as receiver electrodes can be used to transmit, and the electrode designated as transmitter electrodes can be used to receive. A unit cell 308 includes a sensor electrode 306T from a column 304T (e.g., “first sensor electrode”), a sensor electrode 306R from a column 304R (e.g., “second sensor electrode”), and a sensor electrode 306E from a column 304E (e.g., “third sensor electrode”). The sensor electrodes 306 in the unit cell 308 are ohmically isolated from each other by use of insulating materials or a physical gap formed between the electrodes to prevent them from shorting to each other. The electrode array 302-X comprises repeating instances of the unit cell 308.

In the example shown, the sensor electrodes in the sensor electrode pattern 300 are rectangular in shape. However, in general a variety of other sensor electrode shapes may be used. Within the unit cell 308, the sensor electrodes 306T, 306R, and 306E are staggered across the width of the electrode array 302-X. In other words, the sensor electrode 306R is disposed at least partially between the sensor electrodes 306T and 306E. When the unit cell 308 is repeated in an electrode array 302-X, a sensor electrode 306R overlaps sensor electrodes 306T and 306E from two different instances of the unit cell 308. In another embodiment, the sensor electrode 306R is substantially aligned with the sensor electrodes 306T and 306E within the unit cell 308. Thus, the sensor electrode 306R can be disposed entirely between the sensor electrodes 306T and 306E without overlapping sensor electrodes in another instance of the unit cell 308.

While a pattern of rectangular sensor electrodes is illustrated in FIG. 3B, this configuration is not meant to be limiting and in other embodiments, various other non-rectangular sensor electrode shapes may be used. Moreover, the number of sensor electrodes in the unit cell 308, and the arrangement thereof, can vary from one embodiment to another depending on the shape of the sensor electrodes. In general, the unit cell 308 includes a transmitter electrode, a receiver electrode, and an undifferentiated electrode in some arrangement capable of being repeated. While the electrode pattern 300 is shown as having a single type of unit cell 308 repeated, in some embodiments, multiple types of unit cells can be used. For example, a given electrode array 302-X can be formed by an alternating sequence of two different unit cells, each having a different configuration of sensor electrodes.

FIG. 3C is a schematic top view of an electrode array 302-X of the electrode arrays 302 according to another embodiment. A unit cell 308A includes a sensor electrode 310T from the column 304T (e.g., “first sensor electrode”), a sensor electrode 310R from the column 304R (e.g., “second sensor electrode”), and a sensor electrode 310E from the column 304E (e.g., “third sensor electrode”). The sensor electrodes 310 in the unit cell 308 are ohmically isolated from each other by use of insulating materials or a physical gap formed between the electrodes to prevent them from shorting to each other. The electrode array 302-X comprises repeating instances of the unit cell 308. The sensor electrode 310R comprises a single electrode that spans all instances of the unit cell 308 in the electrode array 302-X. Thus, the “second sensor electrode” in the unit cell 308 comprises a portion of the sensor electrode 310R.

As the sensor electrodes in the sensor electrode pattern 300 are disposed on a substrate within the display device (e.g., color filter glass), the sensor electrodes may be comprised of a substantially transparent material (e.g., ATO, ITO, ClearOhm™) or they may be comprised of an opaque material and aligned with the pixels of the display device. Sensor electrodes may be considered substantially transparent in a display device if their reflection (and/or absorption) of light impinging on the display is such that human visual acuity is not disturbed by their presence. This may be achieved by matching indexes of refraction, making opaque lines narrower, reducing fill percentage or making the percentage of material more uniform, reducing spatial patterns (e.g. moire) that are with human visible perception, and the like. In some embodiments, multiple electrodes of an electrode type may be conductively coupled to the same trace 303. For example, one of the traces 303T may conductively couple to multiple sensor electrodes in column 304T.

Each sensor electrode in the sensor electrode pattern 300 is conductively coupled to a trace 303. For example, as shown in the electrode array 302-X, the sensor electrodes in column 304T are coupled to traces 303T and the sensor electrodes in column 306E are coupled to traces 303E. The traces coupled to the sensor electrodes in column 306R are omitted for clarity.

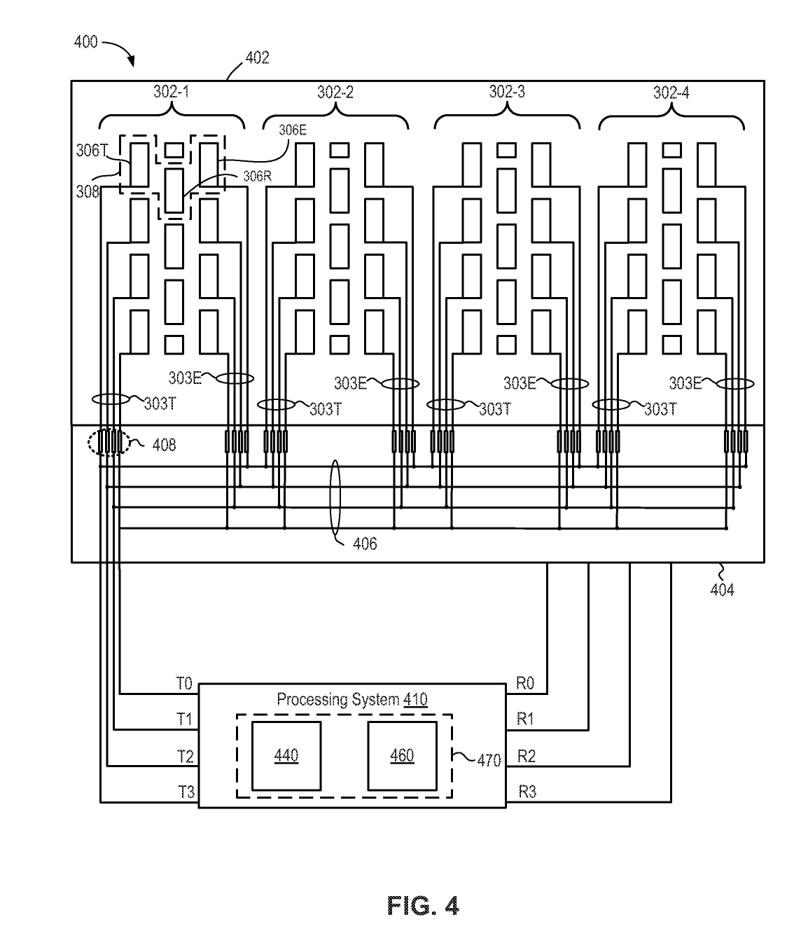

FIG. 4 is a schematic top view of a configuration 400 of the input device 100 that that may be used to sense input object(s) in the sensing region 120. The configuration 400 includes a substrate 402 having the sensor electrode pattern 300 formed thereon. The substrate 402 can be part of a layer in a display device, such as the color filter glass layer as described above. The traces 303 of the sensor electrode pattern 300 are coupled to traces 406 on a connection medium 404 by connectors 408. The connection medium 404 can comprise, for example, a flexible printed circuit (FPC). The traces 406 are electrically coupled to a processing system 410 for operating the sensor electrodes for capacitive sensing of input object(s) proximate a touch surface of the display device. In the configuration 400, the traces 406 are configured such that a trace conductively couples the sensor electrode 306T and the sensor electrode 306E in each instance of the unit cell 308. In the example, the sensor electrode pattern 300 includes four instances of the unit cell 308 in each array 302, designated T0, T1, T2, and T3. Hence, the traces 406 includes four traces likewise designated T0, T1, T2, and T3. For purposes of clarity, the trace coupled to the electrode 306R in each instance of the unit cell 308 is omitted from FIG. 4.

The traces 406 are coupled to transmitter channels T0, T1, T2, and T3 of the processing system 410. Additional traces on the connection medium 404 can couple receiver channels R0, R1, R2, and R3 of the processing system 410 to traces 303 coupled to the receiver electrodes. The routing on the connection medium 404 and the substrate 402 that couples the processing system 410 and the receiver electrodes is omitted for clarity. The processing system 410 can include one or more modules, such as a sensor module 440 and a determination module 460. The sensor module 440 and the determination module 460 comprise modules that perform different functions of the processing system 410. In other examples, different configurations of modules can perform the functions described herein. The sensor module 440 and the determination module 460 can include sensor circuitry 470 and can also include firmware, software, or a combination thereof operating in cooperation with the sensor circuitry 470.

In an embodiment, the sensor module 440 can excite or drive sensor electrodes with signals. The terms “excite” and “drive” as used herein encompasses controlling some electrical aspect of the driven element. For example, it is possible to drive current through a wire, drive charge into a conductor, drive a substantially constant or varying voltage waveform onto an electrode, etc. When sensing transcapacitance, the sensor module 440 can drive transmitter electrodes and undifferentiated electrodes with transmitter signals using the transmitter channels T0, T1, T2, and T3. A transmitter signal comprises a modulated signal, and generally includes a shape, frequency, amplitude, and phase.

The sensor module 240 can also receive resulting signals from sensor electrodes. The resulting signals can include effects of transmitter signals, effects of input object(s), effects of noise, or a combination thereof. The sensor module 440 can drive transmitter electrodes while receiving with receiver electrodes, can receive with receiver electrodes without driving transmitter electrodes, and can drive transmitter electrodes without receiving with receiver electrodes. For example, for transcapacitive sensing, the sensor module 440 can drive transmitter signals onto transmitter electrodes while receiving resulting signals on receiver electrodes. For absolute capacitive sensing, the sensor module 440 can receive from sensor electrodes.

The determination module 460 is configured to receive measurements from the sensor module 240 and determine changes in capacitance that occur in response to the presence or absence of input objects. The determination module 406 can output position information based on the changes in capacitance.

In the configuration 400, the transmitter electrodes are shorted (conductively coupled) to the undifferentiated electrodes for each transmitter channel T0, T1, T2, and T3. The configuration 400 maximizes the transcapacitance between those electrodes (e.g., transmitter electrodes and undifferentiated electrodes) and those electrodes receiving (e.g., receiving electrodes). Hence, the strength of the signal received from the receiving electrodes is maximized. The configuration 400 is useful for thicker, lower dielectric display stacks, including display stacks with an air gap between the sensor electrodes and the touch surface.

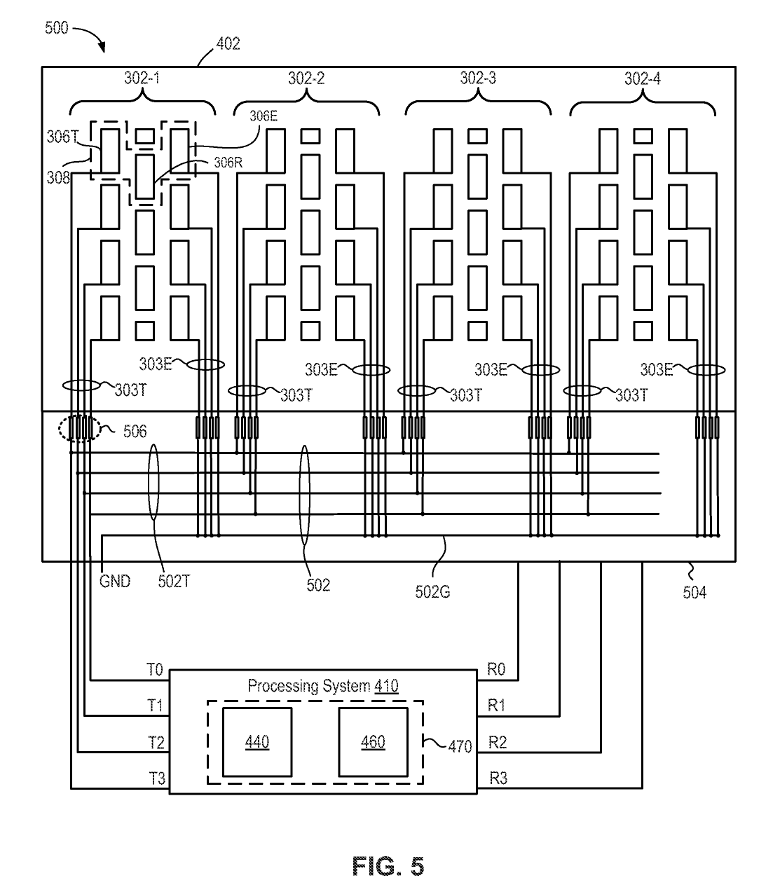

FIG. 5 is a schematic top view of another configuration 500 of the input device 100 that that may be used to sense input object(s) in the sensing region 120. Elements of FIG. 5 that are the same or similar to those of FIG. 4 are designated with identical reference numerals. The configuration 500 includes the substrate 402 having the sensor electrode pattern 300 formed thereon. As discussed above, the substrate 402 can be part of a layer in a display device, such as the color filter glass layer. The traces 303 of the sensor electrode pattern 300 are coupled to traces 502 on a connection medium 504 by connectors 506. The traces 502 include traces 502T configured to receive transmitter signals and a trace 502G configured to receive reference voltage (e.g., ground). The connection medium 504 can comprise, for example, an FPC. The traces 502T are electrically coupled to the processing system 410 for operating the sensor electrodes for capacitive sensing of input object(s) proximate a touch surface of the display device. In the configuration 500, the trace 502G is configured such that a trace conductively couples the sensor electrode 306E in each instance of the unit cell 308 (e.g., the undifferentiated electrodes are coupled to a common bus of the connection medium 504, labeled “GND”). In a given array 302, the sensor electrode 306T in each instance of the unit cell 308 is coupled to a separate one of the traces 502T. For purposes of clarity, the trace coupled to the electrode 306R in each instance of the unit cell 308 is omitted from FIG. 5. The traces 502T are coupled to transmitter channels T0, T1, T2, and T3 of the processing system 410.

In the configuration 500, the undifferentiated electrodes are shorted together by the GND trace 502G. The configuration 500 increases coupling between an input object (e.g., a user's finger) and the system ground of the input device 100, which improves LGM performance. The configuration 500 is useful for thinner, higher dielectric display stacks.

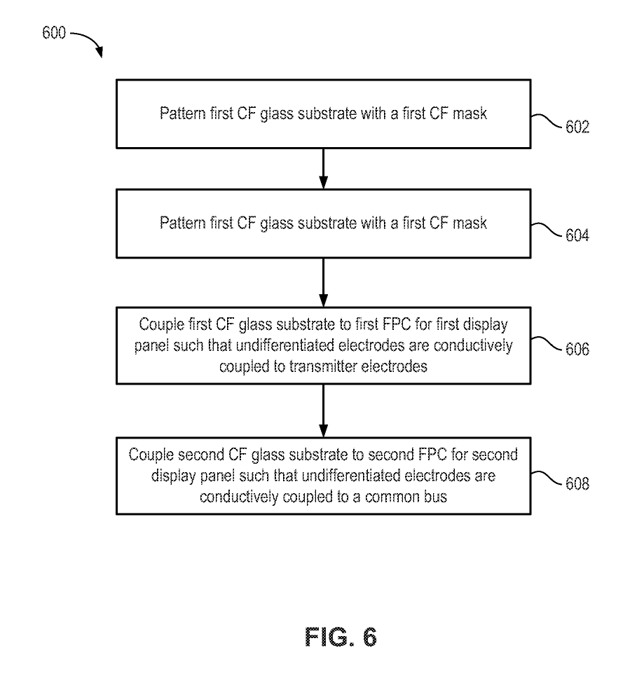

FIG. 6 is a flow diagram depicting an example method 600 of manufacturing display panels. The method 600 begins at step 602, where a first color filter (CF) glass substrate that has been patterned with a first CF mask is received. The first CF mask generates the electrode sensor pattern 300 described above. In general, the sensor electrode pattern generated by the first CF mask includes a first plurality of electrodes having transmitter electrodes, receiver electrodes, and undifferentiated electrodes. At step 604, a second CF glass substrate that has been patterned with the first CF mask is received. Thus, the second CF glass substrate also includes the sensor electrode pattern 300 described above.

At step 606, the first CF glass substrate is coupled to a first FPC for a first display panel such that the undifferentiated electrodes of the first plurality of electrodes are each conductively coupled to one or more of the transmitter electrodes of the first plurality of electrodes. For example, the first FPC can be configured similarly to the connection medium 404 in the configuration 400 of FIG. 4. At step 608, the second CF glass substrate is coupled to a second FPC for a second display panel such that the undifferentiated electrodes of the second plurality of electrodes are coupled to a common bus on the FPC. For example, the second FPC can be configured similarly to the connection medium 504 of the configuration 500 of FIG. 5.

Accordingly, the method 600 can be performed to manufacture two different display panels, each having the same sensor electrode pattern disposed on a layer thereof (e.g., CF glass). The first and second display patterns can have different stack configurations. For example, the first display panel can have a thicker, lower dielectric stack, and the second display panel can have a thinner, higher dielectric stack. The first and second display panels can be manufactured using a common mask for patterning the layer having the sensor electrode pattern, such as a common CF mask (e.g., the first CF mask). The capacitive sensing configuration of the sensor electrode pattern is modified external to the substrate on the respective first and second FPCs. In this manner, an LCM can use only a single CF mask, which reduces cost and complexity in the manufacture of different display panels. The capacitive sensing configuration can be optimized for the given display configuration by modifying the connection medium (e.g., FPC) between the sensor electrode pattern and the processing system.

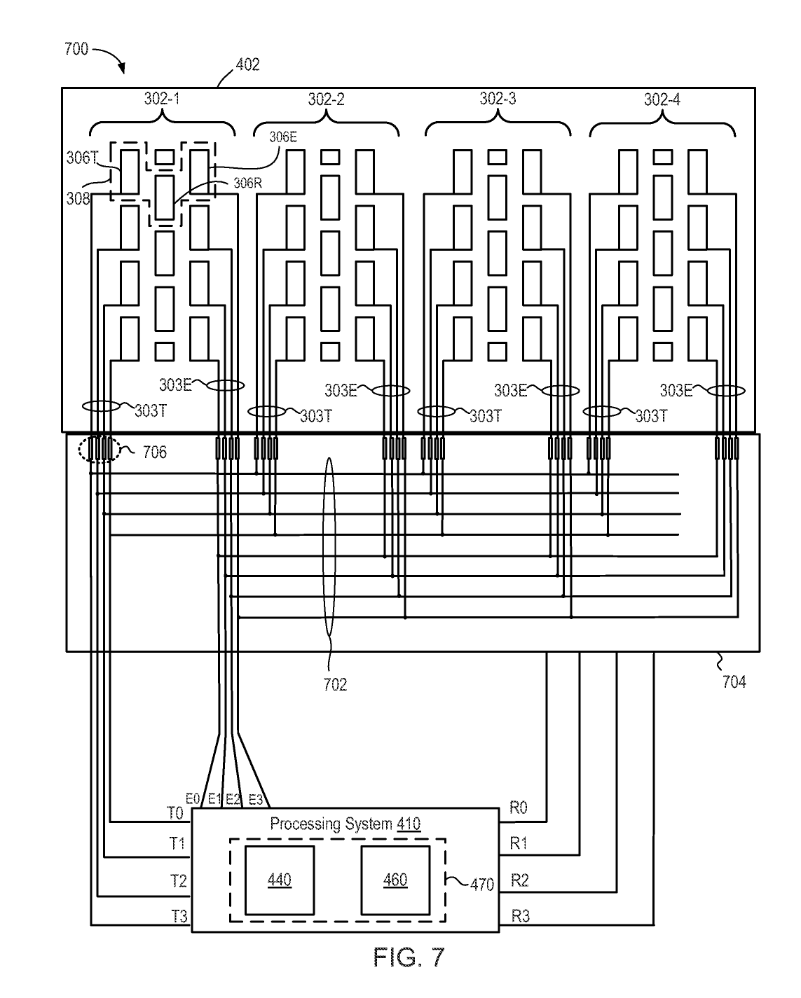

FIG. 7 is a schematic top view of another configuration 700 of the input device 100 that that may be used to sense input object(s) in the sensing region 120. Elements of FIG. 7 that are the same or similar to those of FIG. 4 are designated with identical reference numerals. The configuration 700 includes the substrate 402 having the sensor electrode pattern 300 formed thereon. As discussed above, the substrate 402 can be part of a layer in a display device, such as the color filter glass layer. The traces 303 of the sensor electrode pattern 300 are coupled to traces 702 on a connection medium 704 by connectors 706. The connection medium 704 can comprise, for example, an FPC. The traces 702 are electrically coupled to the processing system 410 for operating the sensor electrodes for capacitive sensing of input object(s) proximate a touch surface of the display device. In the configuration 700, the traces 702 are configured such that individual trances are respectively coupled to the sensor electrode 306T and the sensor electrode 306E in each instance of the unit cell 308 in a given electrode array 302. For purposes of clarity, the trace coupled to the electrode 306R in each instance of the unit cell 308 is omitted from FIG. 7. The traces 702 are coupled to transmitter channels T0, T1, T2, and T3 and undifferentiated channels E0, E1, E2, and E3 of the processing system 410.

In the configuration 700, the processing system 410 can selectively and dynamically implement the connection scheme of either FIG. 4 or FIG. 5 in response to an instruction. That is, in one scheme, the processing system 410 can drive the channels T0/E0, T1/E1, T2/E2, and T3/E3 with transmitter channels to implement the connection scheme described in FIG. 4 above (i.e., the transmitter electrodes are effectively shorted with the undifferentiated electrodes). In another scheme, the processing system 410 can drive the channels T0, T1, T2, and T3 with transmitter signals, and couple a system ground or other substantially constant voltage to the channels E0, E1, E2, and E3 to implement the connection scheme described in FIG. 5 above.

Thus, the embodiments and examples set forth herein were presented in order to best explain the present invention and its particular application and to thereby enable those skilled in the art to make and use the invention. However, those skilled in the art will recognize that the foregoing description and examples have been presented for the purposes of illustration and example only. The description as set forth is not intended to be exhaustive or to limit the invention to the precise form disclosed.

What is claimed is:

1. A capacitive image sensor, comprising:
a first sensor electrode disposed on a first surface of a substrate configured to transmit a transmitter signal;
a second sensor electrode disposed on the first surface of the substrate configured to receive a resulting signal; and
a third sensor electrode disposed on the first surface of the substrate such that the second sensor electrode is at least partially between the first sensor electrode and the third sensor electrode.

2. The capacitive image sensor of claim 1, wherein the third sensor electrode is configured to transmit the transmitter signal.

3. The capacitive image sensor of claim 1, wherein the third sensor electrode is configured to be coupled to a substantially constant voltage.

4. The capacitive image sensor of claim 1, further comprising:
a processing system coupled to the first sensor electrode, the second sensor electrode, and the third sensor electrode through a connection medium.

5. The capacitive image sensor of claim 4, wherein the connection medium is configured to conductively couple the first sensor electrode and the third sensor electrode, and wherein the first sensor electrode and the third sensor electrode are coupled to a transmitter channel of the processing system.

6. The capacitive image sensor of claim 4, wherein the connection medium is configured to conductively couple the third sensor electrode to a common bus, and wherein the processing system is configured to couple a substantially constant voltage to the common bus.

7. The capacitive image sensor of claim 4, wherein the processing system is configured to selectively drive the third sensor electrode with the transmitter signal or with a substantially constant voltage in response to an instruction.

8. The capacitive image sensor of claim 1, further comprising:
a fourth sensor electrode disposed on the first surface of the substrate configured to transmit a transmitter signal;
a fifth sensor electrode disposed on the first surface of the substrate configured to receive a resulting signal; and
a sixth sensor electrode disposed on the first surface of the substrate such that the fifth sensor electrode is at least partially between the fourth sensor electrode and the sixth sensor electrode.

9. The capacitive image sensor of claim 8, wherein the first sensor electrode and the fourth sensor electrode are in a first column of sensor electrodes on the first surface of the substrate, the second sensor electrode and the fifth sensor electrode are in a second column of sensor electrodes on the first surface of the substrate, and the third sensor electrode and the sixth sensor electrode are in a third column of sensor electrodes on the first surface of the substrate.

10. A method of manufacturing display panels, comprising:
receiving a first color filter (CF) glass substrate patterned using a first CF mask, the first CF glass substrate including a first plurality of electrodes comprising transmitter electrodes, receiver electrodes, and undifferentiated electrodes;
receiving a second CF glass substrate patterned using the first CF mask, the second CF glass substrate including a second plurality of electrodes comprising transmitter electrodes, receiver electrodes, and undifferentiated electrodes;
coupling the first CF glass substrate to a first flexible printed circuit (FPC) for a first display panel such that the undifferentiated electrodes of the first plurality of electrodes are each conductively coupled to one or more of the transmitter electrodes of the first plurality of electrodes; and
coupling the second CF glass substrate to a second FPC for a second display panel such that the undifferentiated electrodes of the second plurality of electrodes are coupled to a common bus.

11. The method of claim 10, wherein the undifferentiated electrodes in the first plurality of electrodes are configured to transmit transmitter signals, and wherein the undifferentiated electrodes in the second plurality of electrodes are configured to be driven with a substantially constant voltage.

12. The method of claim 10, wherein the undifferentiated electrodes and the transmitter electrodes of the first plurality of electrodes are configured to be conductively coupled to a transmitter channel of a processing system.

13. The method of claim 10, wherein the undifferentiated electrodes of the second plurality of electrodes are configured to be coupled to a system ground of a processing system.

14. The method of claim 10, wherein a thickness of first display panel is greater than a thickness of the second display panel.

15. A processing system for a capacitive input device, comprising:
a sensor module including sensor circuitry coupled to a plurality of sensor electrodes on a first surface of a substrate, the sensor module configured to:
drive first sensor electrodes of the plurality of sensor electrodes with transmitter signals;
receive resulting signals from second sensor electrodes of the plurality of sensor electrodes; and
drive third sensor electrodes of the plurality of sensor electrodes with the transmitter signals or a substantially constant voltage, the third sensor electrodes disposed on the first surface of the substrate such that the second sensor electrodes are between the first sensor electrodes and the third sensor electrodes.

16. The processing system of claim 15, wherein the sensor module is coupled to the plurality of sensor electrodes through a connection medium that shorts the first sensor electrodes and the third sensor electrodes, the sensor module configured to couple the first sensor electrodes and the third sensor electrodes to a transmitter channel based on the connection medium.

17. The processing system of claim 15, wherein the sensor module is coupled to the plurality of sensor electrodes through a connection medium that shorts the third sensor electrodes, the sensor module configured to couple the substantially constant voltage to the third sensor electrodes based on the connection medium.

18. The processing system of claim 17, wherein the substantially constant voltage is a system ground.

19. The processing system of claim 15, wherein the sensor module is configured to selectively drive the third sensor electrodes with either the transmitter signals or the substantially constant voltage in response to an instruction.

20. The processing system of claim 15, wherein the first sensor electrodes are in a first column of sensor electrodes on the first surface of the substrate, the second sensor electrodes are in a second column of sensor electrodes on the first surface of the substrate, and the third sensor electrodes are in a third column of sensor electrodes on the first surface of the substrate.
